(19) United States
(12) Patent Application Publication
(10) Pub. No.: US 2020/0228885 A1
(43) Pub. Date: Jul. 16, 2020

(54) MONITORING SYSTEM, SERVER APPARATUS, AND PROGRAM

(71) Applicant: NOVARS INC., Tokyo (JP)

(72) Inventor: Kazuhiro KOYAMA, Tokyo (JP)

(21) Appl. No.: 16/827,957

(22) Filed: Mar. 24, 2020

Related U.S. Application Data
(63) Continuation of application No. PCT/JP2018/030708, filed on Aug. 20, 2018.

(30) Foreign Application Priority Data
Sep. 27, 2017 (JP) 2017-186940

(51) Int. Cl. H04Q 9/02; H01M 10/48; G01R 19/00

(52) U.S. Cl. CPC H04Q 9/02; H01M 10/48; G01R 19/0092; H04Q 2209/82; H04Q 2209/40; H04Q 2209/50; H01M 2220/10

(57) ABSTRACT

A electric cell type powersupply device includes a battery housing that houses a battery for supplying electricity to a load device, an operation detecting unit that detects an operation of a manual operating unit based on a fluctuation in current flowing between the load device and the battery, and a first transmitting unit configured to, when the operation of the manual operating unit is detected, transmit operation data on the detection to a server apparatus. The server apparatus includes a receiving unit configured to receive the operation data from the electric cell type powersupply device, a storage unit configured to store the received operation data, an aggregation unit configured to aggregate operations of the manual operating unit based on the stored operation data and to create aggregation data, and a second transmitting unit configured to transmit the aggregation data to an external apparatus over a network.

### CROSS-REFERENCE TO RELATED APPLICATIONS

This application is continuation application of International Patent Application No. PCT/JP2018/030708 filed on Aug. 20, 2018, which is based upon and claims the benefit of priority from the prior Japanese Patent Application No. 2017-186940, filed Sep. 27, 2017 the entire contents of which are incorporated herein by reference.

### FIELD

Embodiments described herein relate generally to a monitoring system, a server apparatus, and a program.

### BACKGROUND

Recent years have seen an appearance of various watching-monitoring systems for elderly persons using sensor technology. A watching-monitoring system is, for example, a system in which a human presence sensor is installed in a location in a house that an elderly person always uses, such as a bathroom, and sensor information from the human presence sensor is collected by a server apparatus. A child of the elderly person who is at a location distant from the elderly person can use a portable information terminal such as a smartphone to browse a result of the collection of the sensor information on a watch site provided by a server apparatus. Alternatively, a system including, in place of the human presence sensor, a heart beat sensor directly attached to an elderly person, and a product such as a refrigerator including a sensor that detects open/close of its door on an assumption that the refrigerator is used in a watching system, and the like also appear.

However, in a case where a watching system using a human presence sensor is introduced, its initial cost is high because it is necessary to newly install the human presence sensor in a house. The installation of the human presence sensor at a position visible to a person watched may lead to a psychological burden on the person feeling that someone is watching the person. In addition, in a case where the human presence sensor malfunctions and should be replaced, the replacement operation is not easy for an ordinary person because the human presence sensor must be subject to certain level of alignment for its replacement; and if installation of a human presence sensor is made in an incorrect direction, this results in failure to collect proper sensor information. In a case where a watching system using a heart beat sensor is introduced, it is required that the heart beat sensor is properly fitted to a person watched; however, because of the effort required to fit the heart beat sensor, it is likely that the heart beat sensor is not fitted properly, failing to provide proper information. As seen from the above, introduction of an existing watching system is difficult from viewpoints of initial cost, maintainability, and collection of proper information.

### SUMMARY OF INVENTION

### Technical Problem

An objective is to provide a monitoring system that is easy for a user to introduce.

### Solution to Problem

A monitoring system according to the present embodiment is a system that monitors operation of a load device including a manual operating unit. The monitoring system includes an electric cell type powersupply device to be inserted into an electric cell box of a load device, and a server apparatus to be connected to the electric cell type powersupply device over a network. The electric cell type powersupply device includes a battery housing that houses a battery for supplying electricity to the load device, an operation detecting unit that detects an operation of the manual operating unit based on a fluctuation in current flowing between the load device and the battery, and a first transmitting unit configured to, when the operation of the manual operating unit is detected, transmit operation data indicating the operation of the manual operating unit to the server apparatus over the network. The server apparatus includes a receiving unit configured to receive the operation data from the electric cell type powersupply device, a storage unit configured to store the received operation data, an aggregation unit configured to aggregate operations of the manual operating unit based on the stored operation data and to create aggregation data, and a second transmitting unit configured to transmit the aggregation data to an external apparatus over the network.

### BRIEF DESCRIPTION OF THE VIEWS OF THE DRAWING

FIG. 1 is a diagram illustrating a general configuration including a monitoring system according to the present embodiment.

FIG. 2 is a diagram illustrating a configuration of the monitoring system illustrated in FIG. 1.

FIG. 3 is a perspective view illustrating an appearance of an electric cell type powersupply device illustrated in FIG. 1.

FIG. 4 is a diagram illustrating an internal structure of the electric cell type powersupply device illustrated in FIG. 3.

FIG. 5 is an equivalent circuit diagram of the electric cell type powersupply device illustrated in FIG. 3.

FIG. 6 is a diagram illustrating an electric cell type powersupply device management table that is managed by a server apparatus illustrated in FIG. 1.

FIG. 7 is a diagram illustrating a result of an aggregation process of an operation history of a manual operating unit of a load device performed by the server apparatus illustrated in FIG. 1.

FIG. 8 is a diagram illustrating an operation history page that is displayed on a user terminal illustrated in FIG. 1.

FIG. 9 is a diagram illustrating an operation history managed by the server apparatus illustrated in FIG. 1.

### DETAILED DESCRIPTION

A monitoring system according to the present embodiment includes electric cell type powersupply devices and a server apparatus. Each electric cell type powersupply device has a shape and dimensions conforming to the battery standard. Each electric cell type powersupply device houses a battery that is smaller than the electric cell type powersupply device. Each electric cell type powersupply device is inserted in an electric cell box of an external load device to be monitored (hereinafter, referred to as load device) and supplies electricity to the load device. The load device is equipped with a manual operating unit that a user manually operates. Typical examples of the load device include a remote controller of a television or an air conditioner, a lamp, a wireless keyboard, a mouse, a scale, a flashlight, and a toy. In a case where the load device is a remote controller for remotely operating a sound volume, a channel, and the like of a television, the manual operating unit includes a plurality of buttons.

When the manual operating unit of the load device is operated, current between the battery housed in the electric cell type powersupply device and the load device fluctuates. The electric cell type powersupply device has a function of detecting the fluctuation of the current. The electric cell type powersupply device has a function of transmitting data indicating that the current fluctuation has been detected, that is, the manual operating unit of the load device has been operated (operation data), to the server apparatus over a public telecommunication network (Internet link). Simply inserting the electric cell type powersupply device into an electric cell box of the load device as described above enables a manual operation of the load device to be detected and the server apparatus to be notified of operation data on the manual operation. Based on the operation data received from the electric cell type powersupply device, the server apparatus aggregates manual operations of the load device and provides a result of the aggregation to a predetermined user terminal.

The monitoring system according to the present embodiment will be described with reference to the drawings. In the following description, the same reference numerals denote components having substantially identical functions and structures, and the repeated description thereof is made only when necessary.

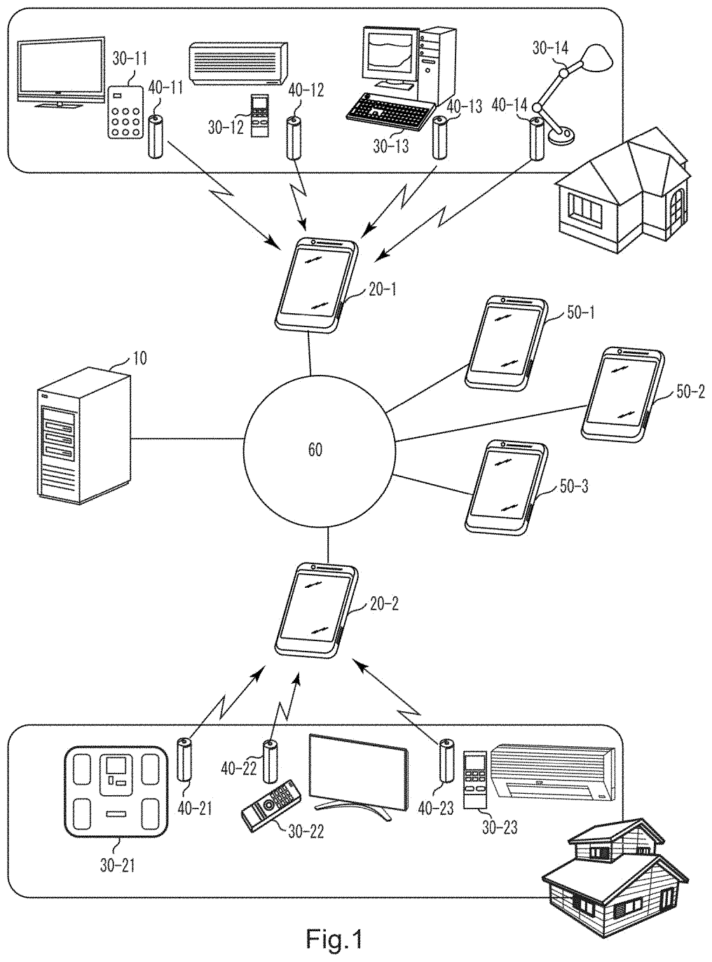

As illustrated in FIG. 1, the monitoring system includes a server apparatus 10. To this server apparatus 10, a plurality of relay terminals 20 (20-1 and 20-2) and a plurality of user terminals 50 (50-1, 50-2, and 50-3) are connected over a network 60. To the relay terminal 20-1, a plurality of electric cell type powersupply devices 40-11, 40-12, 40-13, and 40-14 are connected in conformity to a near field communication (NFC) standard such as Bluetooth®. Similarly, to the relay terminal 20-2, a plurality of electric cell type powersupply devices 40-21, 40-22, and 40-23 are connected in conformity to Bluetooth®.

The user terminals 50 are information communication terminals possessed by users who use a monitoring service provided by the monitoring system, and examples of the user terminals 50 include smartphones, tablets, and PCs. Using the user terminals 50, the users can access a monitor site provided by the server apparatus 10 to browse operation histories of manual operating units of load devices 30.

The electric cell type powersupply devices 40 each functionally include an operation detecting unit that detects an operation of a manual operating unit included in a load device 30 based on a fluctuation in current flowing between the load device 30 and an inside battery, and a transmitting unit that transmits operation data to a relay terminal 20 when the operation of the manual operating unit is detected.

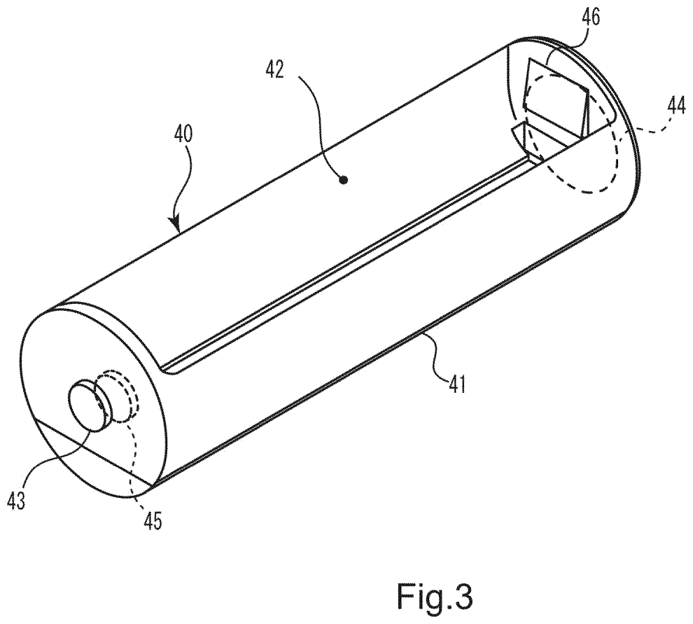

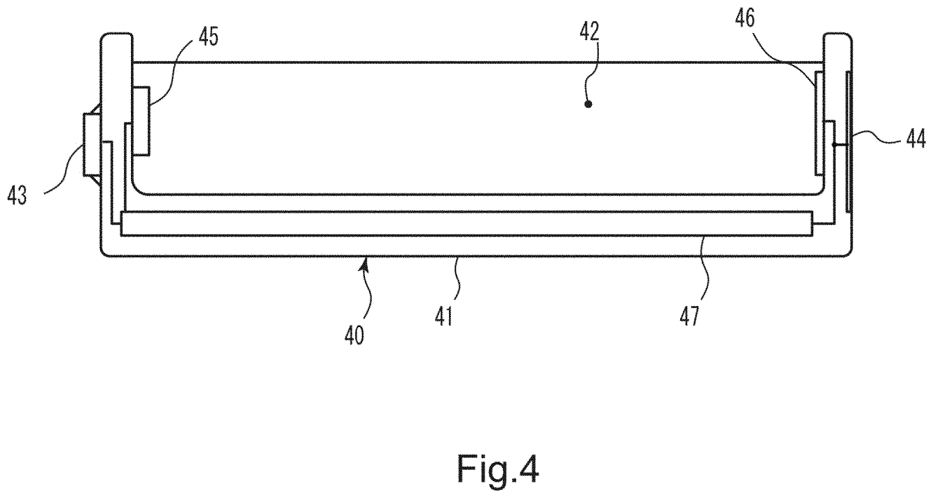

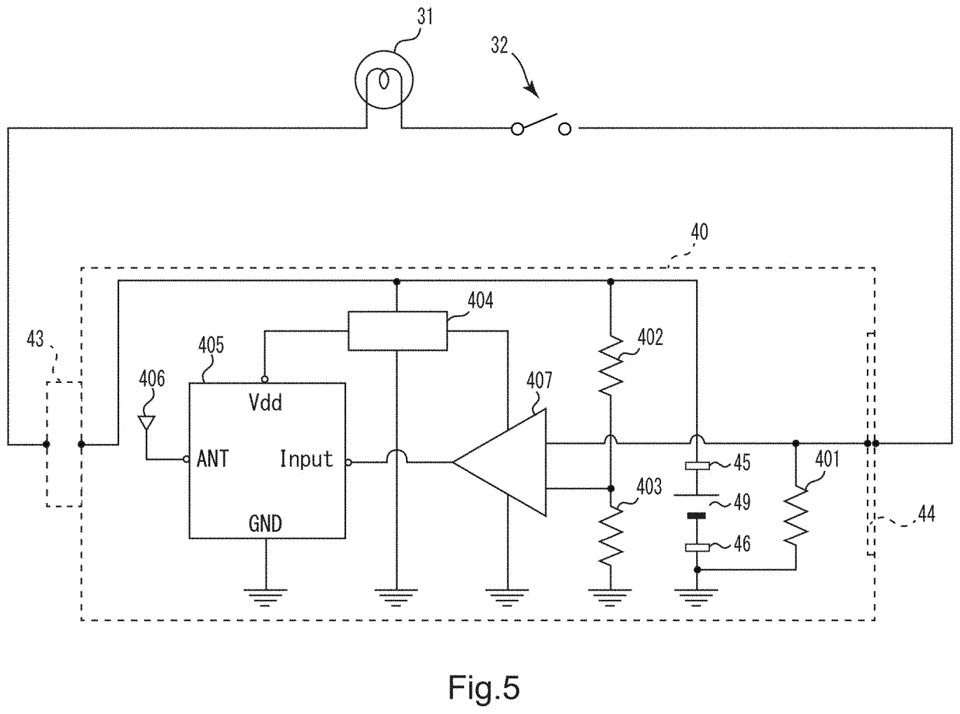

FIG. 3 is a perspective view illustrating an appearance of an electric cell type powersupply device 40 illustrated in FIG. 1. FIG. 4 is a cross-sectional view illustrating an internal structure of the electric cell type powersupply device 40 illustrated in FIG. 1. FIG. 5 is an equivalent circuit diagram of the electric cell type powersupply device 40 illustrated in FIG. 1. The electric cell type powersupply device 40 is configured in accordance with a shape and dimensions conforming to the battery standard. The description will be made assuming that the electric cell type powersupply device 40 conforms to the AA battery standard. The electric cell type powersupply device 40 includes a cylindrical-shaped case 41 that has a height and diameter conforming to the AA battery standard. At front and rear outer end faces of the case 41, an outer positive terminal 43 and an outer negative terminal 44 are provided in conformity to the AA battery standard. The electric cell type powersupply device 40 includes a cylindrical-shaped battery housing 42 that houses an AAA battery (inserted battery). At centers of front and rear inner end faces of the battery housing 42, an inner positive terminal 45 and an inner negative terminal 46 are attached as conductive plates. The battery housing 42 has a cylinder central axis that is offset with respect to a cylinder central axis of the case 41 in a radial direction. This offset provides a small space between the inner face of the case 41 and the outer face of the battery housing 42. This small space houses an electronic circuit substrate 47 that provides various functions of the electric cell type powersupply device 40. A circumferential surface of the case is partially cut out in an oval shape on an opposite side of the central axis of the case 41 to a side on which the electronic circuit substrate 47 is disposed. The cut-out has a length that is equal to or slightly shorter than a length of the AAA battery and has a width that is slightly larger than a width of the AAA battery. Through this cut-out, a user can insert and extract the AAA battery (housed battery) into and from the battery housing 42.

When the AAA battery is housed in the battery housing 42, a positive terminal of the AAA battery comes into contact with the inner positive terminal 45, and a negative terminal of the AAA battery comes into contact with the inner negative terminal 46. The inner positive terminal 45 and the inner negative terminal 46 are electrically connected to the outer positive terminal 43 and the outer negative terminal 44, respectively, with cables or the like. In addition, the inner positive terminal 45 and the outer positive terminal 43 are electrically connected to the electronic circuit substrate 47.

FIG. 5 is an equivalent circuit diagram of the electric cell type powersupply device 40. Here, an example in which the electric cell type powersupply device 40 is solely inserted into an electric cell box of a lamp as the load device will be described. To the electric cell type powersupply device 40, a light bulb 31 and a manual operating unit 32 of the lamp are connected in series. On the electronic circuit substrate 47, a detection resistor 401, a comparator 407, an RFIC 405, and a DC-DC converter 404 are mounted. The detection resistor 401 converts current flowing through the light bulb 31 into voltage. The comparator 407 compares a voltage across the detection resistor 401 (detected voltage) with a reference voltage and outputs a signal based on a result of the comparison. Based on the signal output from the comparator 407, the RFIC 405 determines whether an operation of the manual operating unit 32 is present or absent, and in a case where the operation of the manual operating unit 32 is present, the RFIC 405 transmits operation data including an ID that identifies the electric cell type powersupply device 40 (hereinafter, referred to as electric cell type powersupply device ID) and a timecode that indicates a time of operating the manual operating unit 32, to a relay terminal 20 via an antenna 406. The DC-DC converter 404 uses a battery voltage of a battery 49 housed in the battery housing 42 to generate a drive voltage for the comparator 407 and the RFIC 405.

Components are connected as follows.

The detection resistor 401 is interposed between the inner negative terminal 46 and the outer negative terminal 44. Note that the detection resistor 401 may be interposed between the inner positive terminal 45 and the outer positive terminal 43.

A connection node between the inner negative terminal 46 and the detection resistor 401 is connected to GND. Divider resistors 402 and 403 are connected in series and interposed between a connection node between GND and the inner positive terminal 45 and the outer positive terminal 43. An input terminal of the DC-DC converter 404 is connected to another connection node between the inner positive terminal 45 and the outer positive terminal 43. Output terminals of the DC-DC converter 404 are connected to a power source terminal of the RFIC 405 and a power source terminal of the comparator 407. With this circuit configuration, the inside battery supplies current to the DC-DC converter 404 whether the manual operating unit 32 of the load device 30 is turned ON or OFF, and thus the RFIC 405 and the comparator 407 are always in an ON state.

In the comparator 407, its noninverting input terminal is connected to a connection node between the detection resistor 401 and the outer negative terminal 44, and its inverting input terminal is connected to a connection node between the divider resistor 402 and the divider resistor 403. The comparator 407 receives the voltage across the detection resistor 401 and a voltage across the divider resistor 403. The voltage across the divider resistor 403 is a voltage made by dividing the battery voltage with the divider resistors 402 and 403. Whether the manual operating unit 32 of the load device 30 is turned ON or OFF, the divider resistors 402 and 403 form a closed circuit together with the inside battery. Therefore, the voltage across the divider resistor 403 has a fixed value. The voltage across the divider resistor 403 will be referred to as the reference voltage. In contrast, current flowing through the detection resistor 401 fluctuates in accordance with an operation of the manual operating unit 32 of the load device 30. In a most easy-to-understand example, current flows through detection resistor 401 when the manual operating unit 32 of the load device 30 is in the ON state, and the current does not flow through the detection resistor 401 when the manual operating unit 32 of the load device 30 is in an OFF state. That is, the current flowing through the detection resistor 401 fluctuates in accordance with an operation of the manual operating unit 32 of the load device 30.

A combination of resistance values of the divider resistors 402 and 403, and the detection resistor 401 are adjusted in advance such that a detected voltage becomes higher than the reference voltage when the manual operating unit 32 of the load device 30 is in the ON state, and the detected voltage becomes lower than the reference voltage when the manual operating unit 32 of the load device 30 is in the OFF state. The comparator 407 compares the detected voltage with the reference voltage and outputs a signal at a voltage level based on a result of the comparison. For example, the comparator 407 outputs a voltage signal at a high level when the detected voltage is not less than the reference voltage, and outputs a voltage signal at a low level when the detected voltage is less than the reference voltage.

The RFIC 405 retains a determination table used for determining whether an operation of the manual operating unit 32 is present or absent based on the signal output from the comparator 407. In the determination table, the “low level (detected voltage<reference voltage)” of the voltage level of the signal output from the comparator 407 is associated with an “absence” of an operation of the manual operating unit 32, and the “high level (detected voltage≥reference voltage)” is associated with a “presence” of the operation of the manual operating unit 32.

The RFIC 405 looks up this determination table, determines that the manual operating unit 32 has not been operated when the voltage level of the signal output from the comparator 407 is at the “low level,” and determines that the manual operating unit 32 has been operated when the voltage of the signal output from the comparator 407 is at the “high level.” When determining that the manual operating unit 32 has not been operated, the RFIC 405 does not perform a communicating process. In contrast, when determining that the manual operating unit 32 has been operated, the RFIC 405 performs the communicating process, in which the RFIC 405 transmits operation data including an electric cell type powersupply device ID and a timecode to a relay terminal 20 via the antenna 406. In a case where the transmission of the data to the relay terminal 20 fails, such as where the relay terminal 20 is not connected to the RFIC 405 with Bluetooth®, the RFIC 405 stores the operation data temporarily, and transmits stored items of data collectively to the relay terminal 20 when the connection to the relay terminal 20 is completed. Note that the RFIC 405 may transmit items of operation data collectively to the relay terminal 20 at a predetermined time point, for example, midnight.

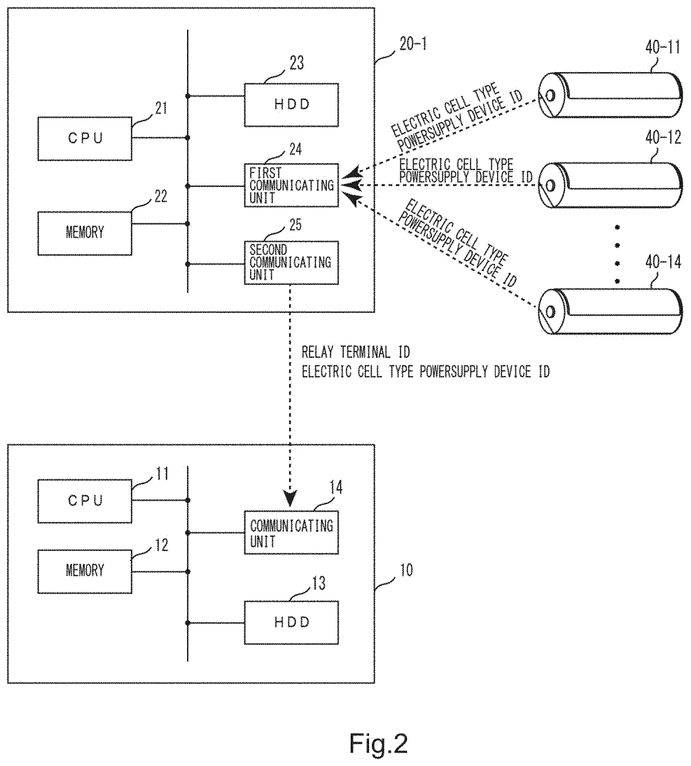

The relay terminal 20 is an information communication terminal having a relay function between the electric cell type powersupply device 40 and the server apparatus 10, and examples of the relay terminal 20 include a smartphone, a tablet, a PC, and a router. As illustrated in FIG. 2, the relay terminal 20-1 includes a CPU 21, a memory 22, a hard disk drive (HDD) 23, a first communicating unit 24 and a second communicating unit 25. The CPU 21 has control over components of the relay terminal 20. The memory 22 functions as, for example, a work area that stores a program and received data temporarily. The first communicating unit 24 performs communication conforming to the Bluetooth® standard to receive a signal including the operation data transmitted from the electric cell type powersupply device 40. The second communicating unit 25 performs communication conforming to the long term evolution (LTE) standard to transmit a signal including the operation data and a relay terminal ID to the server apparatus 10. The HDD 23 stores data relating to application software according to the monitoring service (hereinafter, referred to as monitoring app). By bringing a receiving function of Bluetooth® of the relay terminal 20 to an ON state and running the monitoring app, the relay terminal 20-1 becomes ready to receive items of operation data from the plurality of electric cell type powersupply devices 40-11, 40-12, 40-13, and 40-14 that have been paired with the relay terminal 20-1. When receiving operation data, the relay terminal 20 transmits a signal including the relay terminal ID, and an electric cell type powersupply device ID and the timecode included in the operation data to the server apparatus 10.

The server apparatus 10 includes a storage unit that stores operation histories of manual operating units 32 of the load devices 30, a receiving unit that receives items of operation data transmitted from the electric cell type powersupply devices 40, an aggregation unit that performs an aggregation process on the operation histories of the manual operating unit 32 based on the received items of operation data, and a transmitting unit that transmits a result of the aggregation process to the user terminals 50. These functions are implemented by the server apparatus 10 performing a server program for the monitoring service. The server program for the monitoring service is installed in the server apparatus 10 by connecting the server apparatus 10 to a recording medium in which this server program is recorded.

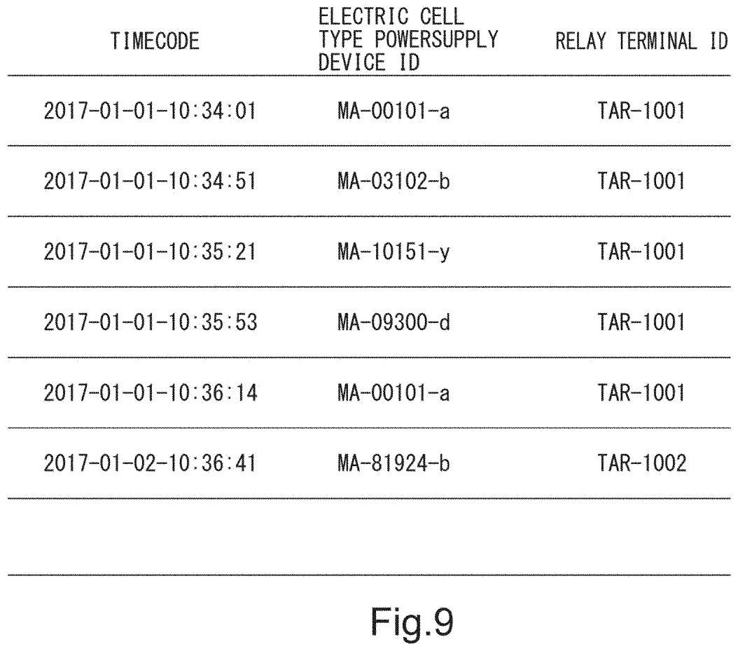

As illustrated in FIG. 2, the server apparatus 10 includes a CPU 11, a memory 12, an HDD 13, and a communicating unit 14. The CPU 11 has control over components of the server apparatus 10. The memory 12 functions as, for example, a work area that stores a program, received data, and data being processed, temporarily. The communicating unit 14 performs a server communicating process conforming to the LTE standard to receive a signal including an electric cell type powersupply device ID, a timecode, and a relay terminal ID, from the relay terminal 20-1. The HDD 13 stores data relating to the server program for the monitoring service (hereinafter, referred to as monitoring server program), data on the operation histories of the load devices 30, data on the electric cell type powersupply device management table, and data on a result of the aggregation of the operation histories. As illustrated in FIG. 9, an operation history includes a plurality of records. Each record includes a timecode, an electric cell type powersupply device ID, and a relay terminal ID. Each record represents an operation of a manual operating unit 32 of a load device 30.

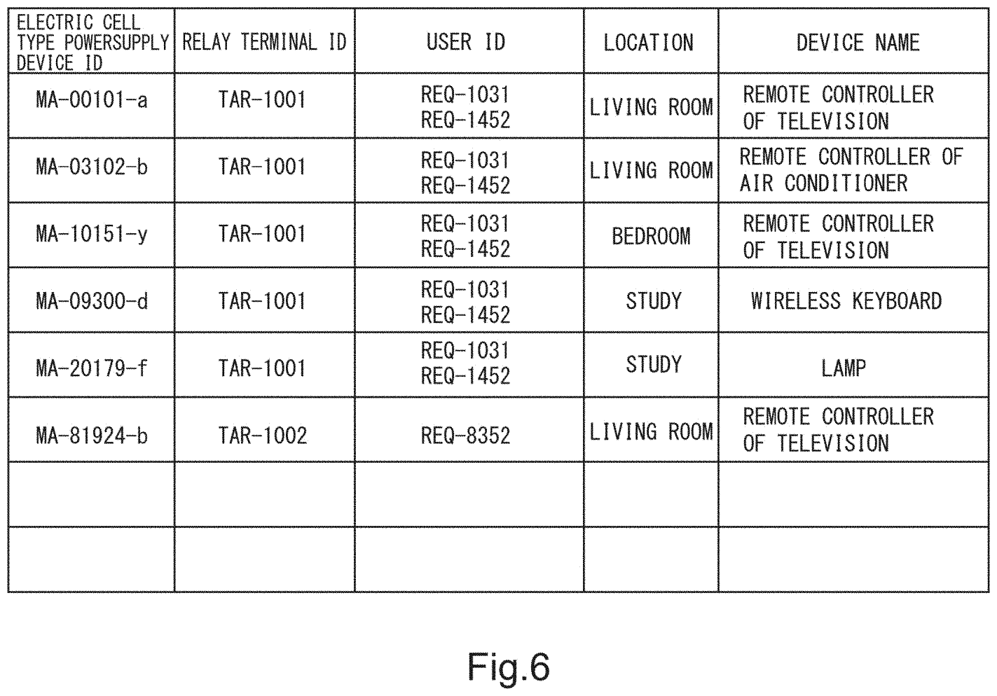

As illustrated in FIG. 6, the electric cell type powersupply device management table includes items “ELECTRIC CELL TYPE POWERSUPPLY DEVICE ID,” “RELAY TERMINAL ID,” “USER ID,” “LOCATION,” and “DEVICE NAME.” The electric cell type powersupply device ID, the relay terminal ID, and the user ID are IDs used for identifying an electric cell type powersupply device 40, a relay terminal 20, and a user, respectively. The electric cell type powersupply device ID is a fixed ID that is assigned in advance to an electric cell type powersupply device 40. The relay terminal ID is a fixed ID that is assigned in advance to a relay terminal 20, an ID that is assigned by the server apparatus 10 according to the present embodiment, or an ID that is assigned by a download server when the monitoring app is downloaded. The user ID is a fixed ID that is assigned in advance to a user terminal 50, a login ID that is used to perform a login to a personalized page in the monitor site, or an ID that is assigned by the server apparatus 10 at a time of user registration to a personalized page in the monitor site. As illustrated in FIG. 6, in the electric cell type powersupply device management table, a single electric cell type powersupply device ID may be associated with a plurality of user IDs. The items “LOCATION” and “DEVICE NAME” indicate, respectively, an installation location and a name of a load device 30 into which an electric cell type powersupply device 40 identified with the item “ELECTRIC CELL TYPE POWERSUPPLY DEVICE ID” is inserted. A registration operation of the items “LOCATION” and “DEVICE NAME” is performed, for example, by a user on the monitor site provided by the server apparatus 10 using a user terminal 50. The items “LOCATION” and “DEVICE NAME” are pieces of information necessary to recognize a load device 30 on an operation history page in the monitor site. Therefore, the registration operation of the items “LOCATION” and “DEVICE NAME” is optional.

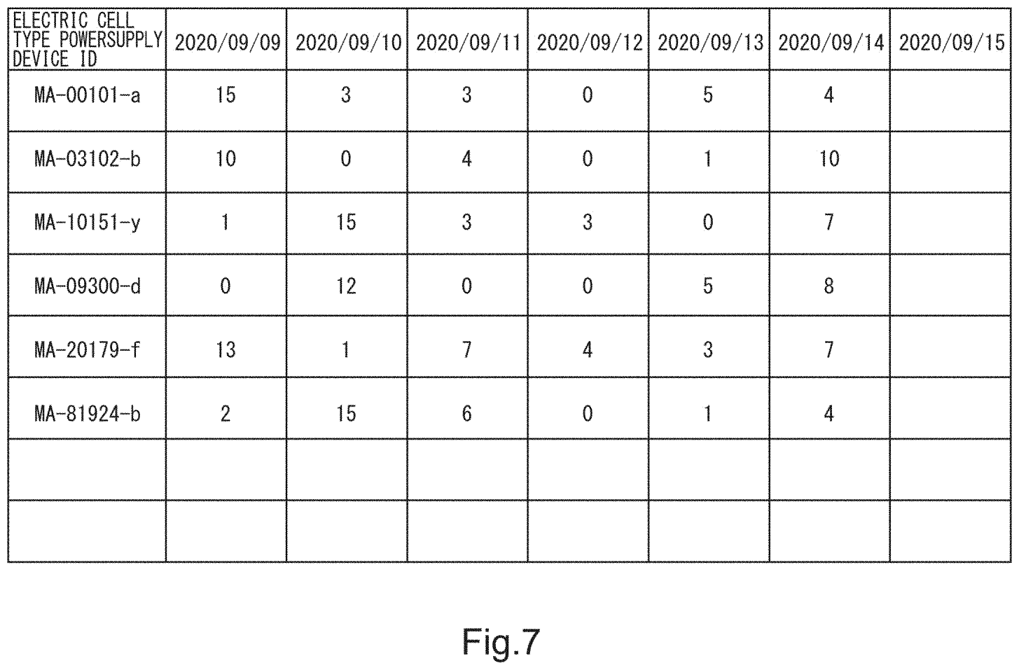

As illustrated in FIG. 7, the result of the aggregation of the operation histories is a result of counting a number of operations for each load device 30 per unit time, per day here. The result of the aggregation of the operation histories and the electric cell type powersupply device management table are managed in a unified manner with electric cell type powersupply device IDs.

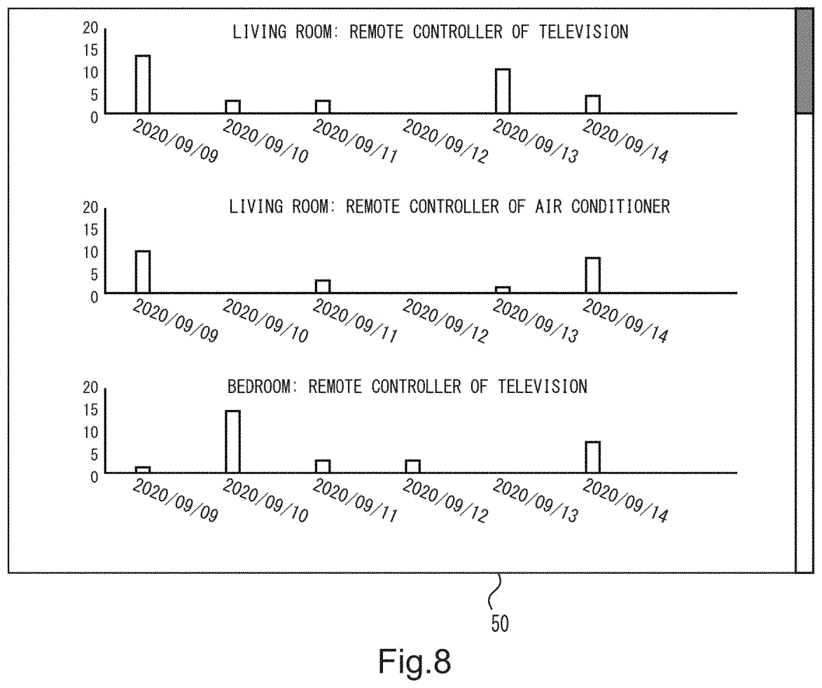

The server apparatus 10 uploads the operation histories to the monitor site on the Internet. A user can browse an operation history of a manual operating unit 32 of a load device 30 associated with a user ID on an operation history page in the monitor site provided by the server apparatus 10 by performing a login to the monitor site with the user ID using a user terminal 50. As illustrated in FIG. 8, an operation history page displayed on a user terminal 50 shows bar charts of respective load devices 30. The bar charts are created based on the result of the aggregation of the operation histories, indicating numbers of operations per day. The bar charts are shown along with installation locations and device names of the load devices 30. By browsing the operation history page, the user can recognize how many times to operate which load device 30 installed at which location. Although the drawing illustrates the bar charts indicating the numbers of operations per day here, a unit of the aggregation is of course not necessarily a day. For example, bar charts shown in narrower time units, in units of six hours, or bar charts shown in wider time units, in units of a week, can be illustrated.

By running the monitoring server program, the server apparatus 10 is ready to receive signals from the relay terminals 20. When receiving a signal from a relay terminal 20, the server apparatus 10 performs a collecting process of operation data on a manual operating unit 32 of a load device 30. That is, the server apparatus 10 determines whether received relay terminal ID and electric cell type powersupply device ID are associated with each other in the electric cell type powersupply device management table. In a case where the received relay terminal ID and electric cell type powersupply device ID are associated with each other in the electric cell type powersupply device management table, it is determined that the manual operating unit 32 of the load device 30 into which an electric cell type powersupply device 40 identified with the electric cell type powersupply device ID is inserted has been operated, and the electric cell type powersupply device ID, the relay terminal ID, and a timecode are stored in a form of an operation history. In addition, a number of operations at a date and time identified with a timecode including the electric cell type powersupply device ID is updated. Upon the update of the result of the aggregation of the operation histories, a bar chart in the operation history page in the monitor site is also updated. In a case where the received relay terminal ID and the electric cell type powersupply device ID are not associated with each other in the electric cell type powersupply device management table, the process described above by the server apparatus 10 is not performed.

As described above, the monitoring system according to the present embodiment can provide a user with information relating to an operation history of a load device 30. In a case where the monitoring system is introduced as a watching system, a user needs to prepare a load device 30 including a manual operating unit 32 and an electric cell box, an electric cell type powersupply device 40 to be inserted into the load device 30, and a relay terminal 20, such as a smartphone, that receives a signal from the electric cell type powersupply device 40 and is connected to the server apparatus 10 over the network 60. However, the load device 30 may be a remote controller for operating a television, an air conditioner, or the like installed in a house of an elderly person watched, there are other kinds of such a load device 30, and thus there is almost no need to prepare a new device to use the monitoring service. The relay terminal 20 may be a smartphone or the like, even elderly persons have started to use smartphones in recent years, and thus there is almost no need to prepare the relay terminal 20. Therefore, the user needs only to prepare an electric cell type powersupply device 40, resulting in a low initial investment cost. The low initial investment cost is a factor in lowering the difficulty of introducing the monitoring system.

Using an electric cell type powersupply device 40 that can be treated as a typical battery dispenses with changing an appearance and an internal configuration of a load device 30 and enables the electric cell type powersupply device 40 to be applied to an existing load device 30. There is no change in usability of the load device 30 across the introduction of the monitoring system, and once the electric cell type powersupply device 40 is inserted into an electric cell box, the electric cell type powersupply device 40 is out of sight of an elderly person in his/her daily life. These mitigate a psychological burden of a person watched, thus becoming a factor in lowering the difficulty of introducing the monitoring system.

A load device to be monitored can be changed easily by changing a load device 30 into which an electric cell type powersupply device 40 is inserted. This can provide a flexibility in an activity such as making a replacement purchase of a television, providing a very high versatility. This high versatility is a factor in lowering the difficulty of introducing the monitoring system.

In addition, even in case the electric cell type powersupply device 40 malfunctions, a replacement operation of the electric cell type powersupply device 40 is the same as a replacement operation of a typical battery, and there is no need to pay attention to a direction of inserting the electric cell type powersupply device 40 into the electric cell box, and thus even an elderly person can perform the replacement operation easily. Therefore, a user only needs to deliver an electric cell type powersupply device 40 for replacement to an elderly person by mail or the like. That is, it can be said that the monitoring system according to the present embodiment is easy to maintain. The easiness of the maintenance is a factor in lowering the difficulty of introducing the monitoring system.

As seen from the above, the monitoring system according to the present embodiment keeps the initial cost of the monitoring system low, is easy to maintain, and has a high versatility, thus having a low difficulty of introducing the monitoring system by a user.

Note that if an electric cell type powersupply device 40 can be connected to the network without a relay terminal 20, the relay terminal 20 is dispensed with. Dispensing with a relay terminal 20 further lowers the difficulty of introducing the monitoring system by a user. The present embodiment does not limit the telecommunications standard between devices. For example, although an electric cell type powersupply device 40 and a relay terminal 20 are connected to each other in conformity to Bluetooth®, they may be connected wirelessly to each other in conformity to another telecommunications standard. A relay terminal 20 may be connected to the network 60 in conformity to another telecommunications standard rather than the LTE standard.

In the present embodiment, the electric cell type powersupply device management table retained by the server apparatus 10 may be managed by a relay terminal 20 or an electric cell type powersupply device 40. Although the timecode indicating a time of operating a manual operating unit 32 is here generated by an electric cell type powersupply device 40, a relay terminal 20 may generate a timecode indicating a time of receiving operation data from the electric cell type powersupply device 40 and transmit the timecode to the server apparatus 10 together with an electric cell type powersupply device ID and a relay terminal ID.

In the present embodiment, a user can check an operation history of a load device 30 on an operation history page for the user in the monitor site provided by the server apparatus 10, but this does not limit a method for providing the user with the operation history of the load device 30. For example, in response to a request from a user terminal 50, the server apparatus 10 may identify an electric cell type powersupply device ID associated with a user ID in the electric cell type powersupply device management table and may provide the user terminal 50 with data relating to an operation history, a location, and a device name associated with the identified electric cell type powersupply device ID, by a notification method such as email. As long as application software that creates an operation history page from data transmitted from the server apparatus 10 is installed on the user terminal 50, the user terminal 50 can automatically create an operation history page from data provided to the user terminal 50.

An electric cell type powersupply device 40 may include a voltage detecting unit that detects a battery voltage of a battery housed in a battery housing 42. In this case, the voltage detecting unit can be provided by configuring the circuit such that a signal made by converting the voltage across the battery into a digital signal is input into the RFIC 405. For example, to a connection node between the outer positive terminal 43 and the inner positive terminal 45 of the electric cell type powersupply device, an input terminal of an AD converter is connected, and an output terminal of the AD converter is connected to another Input terminal of the RFIC 405. In a case where the RFIC 405 has an AD conversion function, the other Input terminal of the RFIC 405 is connected directly to the connection node between the outer positive terminal 43 and the inner positive terminal 45 of the electric cell type powersupply device. Since the RFIC 405 is always in the ON state, the RFIC 405 always receives digital data on the battery voltage. The RFIC 405 transmits operation data including data on the detected battery voltage to a relay terminal 20. The relay terminal 20 transmits data including the data on the battery voltage, an electric cell type powersupply device ID, a timecode, and a relay terminal ID, to the server apparatus 10. The server apparatus 10 provides a user with information relating to the data on the battery voltage, such as a remaining battery power, via the monitor site, email, or the like. This allows the user to prepare for a shortage of the remaining battery power, which further improves maintainability.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### REFERENCE SIGNS LIST

10 . . . server apparatus, 20 . . . relay terminal, 30 . . . load device, 40 . . . electric cell type powersupply device, 50 . . . user terminal, 60 . . . network.

1. A monitoring system monitoring operation of a load device that includes a manual operating unit and an electric cell box for housing a battery, the monitoring system comprising:
an electric cell type powersupply device to be inserted into the electric cell box of the load device; and
a server apparatus to be connected to the electric cell type powersupply device over a network, wherein
the electric cell type powersupply device includes:
a battery housing that houses a battery for supplying electricity to the load device;
an operation detecting unit configured to detect an operation of the manual operating unit based on a fluctuation in current flowing through the load device and the battery; and
a first transmitting unit configured to, when the operation of the manual operating unit is detected, transmit operation data indicating the operation of the manual operating unit to the server apparatus over the network, and
the server apparatus includes:
a receiving unit configured to receive the operation data from the electric cell type powersupply device;
a storage unit configured to store the received operation data;
an aggregation unit configured to aggregate operations of the manual operating unit based on the stored operation data, and to create aggregation data; and
a second transmitting unit configured to transmit the aggregation data to an external apparatus over the network.

2. The monitoring system according to claim 1, wherein the operation data includes an ID used for identifying the electric cell type powersupply device and a timecode indicating a time at which the manual operating unit is operated.

3. The monitoring system according to claim 2, wherein the aggregation unit counts a number of operations of the manual operating unit per unit time based on the ID and the timecode.

4. The monitoring system according to claim 1, wherein
the electric cell type powersupply device further includes a voltage detecting unit configured to detect a battery voltage of the battery, and
the operation data includes data relating to the battery voltage.

5. The monitoring system according to claim 1, wherein
the electric cell type powersupply device further includes:
a case that is formed into a bottomed cylindrical shape having a shape and a size conforming to a battery standard and includes an outer positive electrode terminal and an outer negative electrode terminal on front and rear end faces of the case;
a battery housing that houses the battery inside the case and includes an inner positive terminal and an inner negative terminal that are to come into contact with front and rear terminals of the housed battery, respectively;
a detection resistor interposed between the outer negative electrode terminal and the inner negative terminal; and
a comparator configured to compare a voltage across the detection resistor with a reference voltage, wherein
the operation detecting unit detects an operation of the manual operating unit based on a signal output from the comparator.

6. A server apparatus to be connected to an electric cell type powersupply device over a network, the electric cell type powersupply device being to be inserted into an electric cell box of a load device including a manual operating unit, the server apparatus comprising:
a receiving unit configured to receive operation data from the electric cell type powersupply device, the operation data indicating an operation of the manual operating unit;
a storage unit configured to store the received operation data;
an aggregation unit configured to aggregate operations of the manual operating unit based on the stored operation data and to create aggregation data; and
a transmitting unit configured to transmit the aggregation data to an external apparatus over the network.

7. A computer readable storage medium comprising a program recorded therein, the program causing a computer to implement certain means, the computer being to be connected to an electric cell type powersupply device over a network, the electric cell type powersupply device being to be inserted into an electric cell box of a load device including a manual operating unit, the certain means to be implemented by the computer including:
means for receiving operation data from the electric cell type powersupply device, the operation data indicating an operation of the manual operating unit;
means for storing the received operation data;
means for aggregating operations of the manual operating unit based on the stored operation data, and creating aggregation data; and
means for transmitting the aggregation data to an external apparatus over the network.
